(19) United States
(12) Patent Application Publication
(10) Pub. No.: US 2025/0063814 A1
(43) Pub. Date: Feb. 20, 2025

(54) SEMICONDUCTOR DEVICE

(71) Applicant: Samsung Electronics Co., Ltd., Suwon-si (KR)

(72) Inventors: Eui Bok Lee, Suwon-si (KR); Rak Hwan Kim, Suwon-si (KR); Jong Min Baek, Suwon-si (KR)

(21) Appl. No.: 18/661,872

(22) Filed: May 13, 2024

(30) Foreign Application Priority Data
Aug. 16, 2023 (KR) 10-2023-0106606

(51) Int. Cl. H01L 27/118

(52) U.S. Cl. CPC H01L 27/11807; H01L 2027/11853; H01L 2027/11875

(57) ABSTRACT

A semiconductor device includes a substrate; a first transistor on the substrate; a first contact on a source/drain pattern of the first transistor; a second transistor on the substrate; a second contact on a gate electrode of the second transistor; a first connecting structure that includes at least one first wiring and at least one first via that are alternately stacked on the first contact; a second connecting structure that includes at least one second wiring and at least one second via that are alternately stacked on the second contact; a first connecting via on the first connecting structure; a second connecting via on the second connecting structure; and a connecting wiring on the first connecting via and the second connecting via.

### CROSS-REFERENCE TO RELATED APPLICATION

This application claims priority from Korean Patent Application No. 10-2023-0106606 filed on Aug. 16, 2023, in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor device.

### BACKGROUND

An antenna effect is a phenomenon in which long wirings are charged in an etching process of a metal wiring layer of a semiconductor device. For example, when the metal wiring layer is plasma-etched, if an amount of charge accumulated in a gate electrode connected to the long wiring increases, the insulation of the gate insulating film may degrade and a leak current may occur.

### SUMMARY

Aspects of the present disclosure provide a semiconductor device capable of improving element performance and reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some example embodiments of the present disclosure, a semiconductor device includes a substrate; a first transistor on the substrate; a first contact on a source/drain pattern of the first transistor; a second transistor on the substrate; a second contact on a gate electrode of the second transistor; a first connecting structure that includes at least one first wiring and at least one first via that are alternately stacked on the first contact; a second connecting structure that includes at least one second wiring and at least one second via that are alternately stacked on the second contact; a first connecting via on the first connecting structure; a second connecting via on the second connecting structure; and a connecting wiring on the first connecting via and the second connecting via.

According to some example embodiments of the present disclosure, a semiconductor device includes a substrate; a first transistor on the substrate; a first contact on a source/drain pattern of the first transistor; a second transistor on the substrate; a second contact on a gate electrode of the second transistor; a first connecting structure on the first contact, where the first connecting structure includes at least one first wiring and at least one first via; a second connecting structure on the second contact, where the second connecting structure includes at least one second wiring and at least one second via; a first connecting via on the first connecting structure; a second connecting via on the second connecting structure; and a connecting wiring on the first connecting via and the second connecting via, where in a first direction in which each of the at least one first wiring extends, a length of each of the at least one second wiring is less than a length of each of the at least one first wiring, and a distance between a third wiring at an uppermost part of the at least one first wiring and a fourth wiring at an uppermost part of the at least one second wiring increases as a distance between the third wiring and the substrate increases or as a distance between the fourth wiring and the substrate increases.

According to some example embodiments of the present disclosure, a semiconductor device includes a first cell; a first connecting via on the first cell; a second cell; a second connecting via on the second cell; and a connecting wiring that is on and electrically connects the first connecting via and the second connecting via, where the first cell includes: a first transistor, a first contact on a source/drain pattern of the first transistor, and a first connecting structure that includes at least one first wiring and at least one first via, where the first connecting structure electrically connects the first contact and the first connecting via, where the second cell includes: a second transistor, a second contact on a gate electrode of the second transistor, and a second connecting structure that includes at least one second wiring and at least one second via, where the second connecting structure electrically connects the second contact and the second connecting via.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a diagram of a semiconductor device according to some embodiments;

FIG. 2 is a diagram of the semiconductor device according to some embodiments;

FIG. 3 is a diagram of the semiconductor device according to some embodiments;

FIG. 4 is a diagram of the semiconductor device according to some embodiments;

FIG. 5 is a diagram of the semiconductor device according to some embodiments.

FIG. 6 is a diagram of the semiconductor device according to some embodiments;

FIG. 7 is a diagram of the semiconductor device according to some embodiments;

FIG. 8 is a diagram of the semiconductor device according to some embodiments;

FIG. 9 is a diagram of the semiconductor device according to some embodiments;

FIG. 10 is a diagram of the semiconductor device according to some embodiments;

FIG. 11 is a diagram of the semiconductor device according to some embodiments;

FIG. 12 is a diagram of the semiconductor device according to some embodiments;

FIG. 13 is a diagram of the semiconductor device according to some embodiments; and

FIG. 14 is a diagram of the semiconductor device according to some embodiments.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. As used herein, “an element A is at a same level as element B” refers to at least one surface of element A that is coplanar with at least one surface of element B. As used herein, “an element A is at a lower level than element B” refers to at least one surface of element A that extends from a reference object by a smaller distance than element B extends from the same reference object. As used herein, “an element A is at a higher level than element B” refers to at least one surface of element A that extends from a reference object by a greater distance than element B extends from the same reference object. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

Example embodiments of the present disclosures will now be described more fully with reference to the accompanying drawings, in which example embodiments are shown.

Although drawings of a semiconductor device according to some embodiments show a fin-type transistor (FinFET) including a channel region of a fin-type pattern shape, a transistor including a nanowire or a nanosheet, and a MBCFET™ (Multi-Bridge Channel Field Effect Transistor) as an example, the embodiment is not limited thereto.

The semiconductor device according to some embodiments may, of course, include a tunneling transistor (tunneling FET), a three-dimensional (3D) transistor or a vertical transistor (Vertical FET). The semiconductor device according to some embodiments may, of course, include a planar transistor. In addition, the technical idea of the present disclosure may be applied to a transistor based on two-dimensional material (2D material-based FETs) and a heterostructure thereof. Further, the semiconductor device according to some embodiments may also include a bipolar junction transistor, a laterally diffused metal oxide semiconductor (LDMOS), or the like.

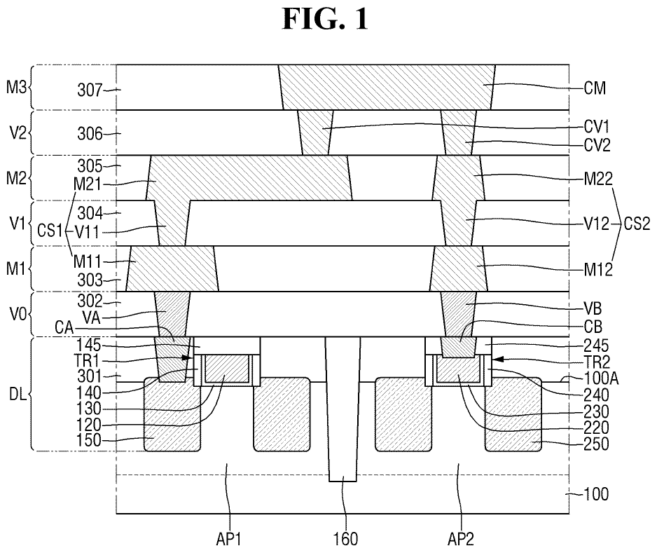

FIG. 1 is a diagram of a semiconductor device according to some embodiments.

Referring to FIG. 1, the semiconductor device according to some embodiments includes a substrate 100, a first transistor TR1, first contacts CA and VA, a first connecting structure CS1, a second transistor TR2, second contacts CB and VB, a second connecting structure CS2, a first connecting via CV1, a second connecting via CV2, and a connecting wiring CM. The first contacts CA and VA include a source/drain contact CA and a first contact via VA. The second contacts CB and VB include a gate contact CV and a second contact via VB.

The substrate 100 may be made of a semiconductor material or include a semiconductor material. The substrate 100 may be a silicon substrate or a silicon-on-insulator (SOI) substrate. In contrast, the substrate 100 may include, but is not limited to, silicon germanium, SGOI (silicon germanium on insulator), indium antimonide, lead tellurium compounds, indium arsenide, indium phosphide, gallium arsenide or gallium antimonide.

An element layer DL includes a first transistor TR1, a source/drain contact CA, a second transistor TR2, a gate contact CB, and a first interlayer insulating film 301.

The first transistor TR1 may include a first active pattern AP1, a first gate electrode 120, a first gate insulating film 130, a first gate spacer 140, a first gate capping pattern 145, and a first source/drain pattern 150. The second transistor TR2 may include a second active pattern AP2, a second gate electrode 220, a second gate insulating film 230, a second gate spacer 240, a second gate capping pattern 245, and a second source/drain pattern 250.

The first active pattern AP1 and the second active pattern AP2 may protrude or extend from an upper side 100A of the substrate 100. The first active pattern AP1 and the second active pattern AP2 may extend long in a first direction. The first active pattern AP1 and the second active pattern AP2 may be separated by a cell separation film 160. The cell separation film 160 may include an insulating material.

The first active pattern AP1 and the second active pattern AP2 may be a part of the substrate 100, or may include an epitaxial layer grown from the substrate 100. The first active pattern AP1 and the second active pattern AP2 may each include, for example, silicon or germanium, which is an elemental semiconductor material. Further, the first active pattern AP1 and the second active pattern AP2 may each include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge), and tin (Sn), or a compound obtained by doping these elements with a group IV element. The group III-V compound semiconductor may be, for example, one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

The first gate electrode 120 may be disposed on the first active pattern AP1. The first gate electrode 120 may intersect the first active pattern AP1. The first gate electrode 120 may extend in a second direction that intersects the first direction along which the first active pattern AP1 extends. The second gate electrode 220 may be disposed on the second active pattern AP2. The second gate electrode 220 may intersect the second active pattern AP2. The second gate electrode 220 may extend in the second direction. The first direction along which the first active pattern AP1 and the second active pattern AP2 extend and the second direction along which the first gate electrode 120 and the second gate electrode 220 extend are directions that are parallel to the upper side 100A of the substrate 100.

The first gate electrode 120 and the second gate electrode 220 may each include, for example, at least one of metal, conductive metal nitride, conductive metal carbonitride, conductive metal carbide, metal silicide, doped semiconductor material, conductive metal oxynitride, and conductive metal oxide.

The first gate insulating film 130 may be disposed between the first gate electrode 120 and the first active pattern AP1. The second gate insulating film 230 may be disposed between the second gate electrode 220 and the second active pattern AP2.

The first gate insulating film 130 and the second gate insulating film 230 may each include silicon oxide, silicon oxynitride, silicon nitride or a high dielectric constant material having a higher dielectric constant than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the first gate insulating film 130 and the second gate insulating film 230 are each shown as being a single film, this example is only for convenience of explanation and is not limited thereto. The first gate insulating film 130 and the second gate insulating film 230 may each include a plurality of films. The first gate insulating film 130 and the second gate insulating film 230 may include an interfacial layer and a high dielectric constant insulating film.

A semiconductor device according to some embodiments may include an NC (Negative Capacitance) FET that uses a negative capacitor. For example, the first gate insulating film 130 and the second gate insulating film 230 may each include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. Using the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium CA, cerium (Ce), dysprosium (Dy), erbium (Er), gadolinium (Gd), germanium (Ge), scandium (Sc), strontium (Sr), and tin (Sn). The type of dopant included in the ferroelectric material film may vary based on the type of ferroelectric material included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. The thickness of the ferroelectric material film may be, for example, but is not limited to, 0.5 to 10 nm. Since a critical thickness that exhibits the ferroelectric properties may vary for each ferroelectric material, the thickness of the ferroelectric material film may vary depending on the ferroelectric material.

As an example, the first gate insulating film 130 and the second gate insulating film 230 may each include one ferroelectric material film. As another example, the first gate insulating film 130 and the second gate insulating film 230 may each include a plurality of ferroelectric material films spaced apart from each other. The first gate insulating film 130 and the second gate insulating film 230 may each have a stacked film structure in which the plurality of ferroelectric material films and the plurality of paraelectric material films are alternately stacked.

The first gate spacer 140 may be disposed on the side walls of the first gate electrode 120. The second gate spacer 240 may be disposed on the side walls of the second gate electrode 220.

The first gate spacer 140 and the second gate spacer 240 may each include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although each of the first gate spacer 140 and the second gate spacer 240 is shown as being a single film, this example is only for convenience of explanation and is not limited thereto.

A first gate capping pattern 145 may be placed on the first gate electrode 120. The second gate capping pattern 245 may be placed on the second gate electrode 220. The first gate capping pattern 145 and the second gate capping pattern 245 may each include, for example, at least one of silicon nitride (SiN), silicon oxynitride (SiON), silicon carbonitride (SiCN), silicon oxycarbonitride (SiOCN), and combinations thereof.

A first source/drain pattern 150 may be disposed on the first active pattern AP1. A second source/drain pattern 250 may be disposed on the second active pattern AP2. The first source/drain pattern 150 and the second source/drain pattern 250 may each include an epitaxial pattern. The first source/drain pattern 150 and the second source/drain pattern 250 may each include a semiconductor material.

A first interlayer insulating film 301 is disposed on the upper side 100A of the substrate 100. The first interlayer insulating film 301 may be disposed on the first source/drain pattern 150 and the second source/drain pattern 250. The first interlayer insulating film 301 may not cover or overlap the upper side of the first gate capping pattern 145.

A source/drain contact CA is disposed on the first source/drain pattern 150. The source/drain contact CA is electrically connected to the first source/drain pattern 150. The source/drain contact CA may be in contact with the first source/drain pattern 150.

A gate contact CB is disposed on the second gate electrode 220. The gate contact CB may penetrate or extend into the second gate capping pattern 245. The gate contact CB is electrically connected to the second gate electrode 220. The gate contact CB may be in contact with the second gate electrode 220.

For example, a width of the source/drain contact CA and a width of the gate contact CB may increase as a distance between the source/drain contact CA/the gate contact CB and the substrate 100 increases. Here, the width is defined on the basis of a direction parallel to the upper side 100A of the substrate 100.

Although the source/drain contact CA and the gate contact CB are each shown as being a single conductive film structure, this example is only for convenience of explanation and is not limited thereto. In one variation, at least one of the source/drain contact CA and the gate contact CB may have multiple conductive film structures.

The first source/drain pattern 150 of the first transistor TR1 is electrically connected to the second gate electrode 220 of the second transistor TR2.

The first contacts CA and VA, the first connecting structure CS1, and the first connecting via CV1 are sequentially stacked on the first source/drain pattern 150. The second contacts CB and VB, the second connecting structure CS2, and the second connecting via CV2 are sequentially stacked on the second gate electrode 220. The connecting wiring CM connects the first connecting via CV1 and the second connecting via CV2. The first source/drain pattern 150 is electrically connected to the connecting wiring CM through the first contacts CA and VA, the first connecting structure CS1, and the first connecting via CV1. The second gate electrode 220 is electrically connected to the connecting wiring CM through the second contacts CB and VB, the second connecting structure CS2, and the second connecting via CV2. The first connecting structure CS1 and the second connecting structure CS2 are not directly connected. The first connecting structure CS1 and the second connecting structure CS2 are connected to each other through the first connecting via CV1, the second connecting via CV2, and the connecting wiring CM.

The connecting wiring CM is a wiring of the lowest layer that connects the first connecting structure CS1 and the second connecting structure CS2, and the first and second connecting vias CV1 and CV2 may be vias of the lowest layer that connects the first connecting structure CS1 and the second connecting structure CS2.

The first connecting structure CS1 includes at least one first wiring M11 and M21 and at least one first via V11 that are alternately stacked on the first contact via VA. The second connecting structure CS2 has a stacked via structure, including at least one second wiring M12 and M22 and at least one second via V12 that are alternately stacked on the second contact via VB. The second connecting structure CS2 includes wirings M11 and M21 disposed on each of the metal layers M1 and M2 one by one, and one via V11 disposed in each via layer V1 one by one.

The width of a first set of at least one first wiring M11 and M21, at least one first via V11, at least one second wiring M12 and M22, and at least one second via V12 may decrease as the distance between the respective component and the substrate 100 increases, and width of a remaining/second set may increase as the distance between the respective component and the substrate 100. This may vary based on the fabricating process of at least one first wiring M11 and M21, at least one first via V11, at least one second wiring M12 and M22, and at least one second via V12.

For example, the element layer DL, the contact via layer V0, the first metal layer M1, the first via layer V1, the second metal layer M2, the second via layer V2, and the third metal layer M3 may be sequentially stacked on the substrate 100. The connecting wiring CM may be placed on the third metal layer M3, and the first connecting via CV1 and the second connecting via CV2 may be placed on the second via layer V2. The first connecting structure CS1 includes a first wiring M11, the first via V11, and a second wiring M21. The second connecting structure CS2 includes a first wiring M12, the second via V12 and a second wiring M22.

The wirings M21 and M22 placed on the uppermost parts of the first connecting structure CS1 and the second connecting structure CS2 are formed by a subtractive process, and at least some of the wirings M11 and M21 and the vias V11 and V12 placed below them are formed by the subtractive process or a semi-damascene process.

The contact via layer V0 includes a second interlayer insulating film 302, a first contact via VA, and a second contact via VB. The first contact via VA and the second contact via VB are disposed inside the second interlayer insulating film 302. The first contact via VA is disposed on the source/drain contact CA. The first contact via VA is electrically connected to the source/drain contact CA. The first contact via VA may be in contact with the source/drain contact CA. The second contact via VB is disposed on the gate contact CB. The second contact via VB is electrically connected to the gate contact CB. The second contact via VB may be in contact with the gate contact CB.

For example, the width of the first contact via VA and the width of the second contact via VB may increase as the distances between the respective components and the substrate 100 increase. A distance between the first contact via VA and the second contact via VB may decrease as the distances between the respective components and the substrate 100 increases. The distance here is defined based on the direction that is parallel to the upper side 100A of the substrate 100.

Although the first contact via VA and the second contact via VB are each shown to have a single conductive film structure, this example is only for convenience of explanation and is not limited thereto. Unlike the shown example, as an example, at least one of the first contact via VA and the second contact via VB may have multiple conductive film structures.

The first metal layer M1 includes a third interlayer insulating film 303, a first wiring M11 and a first wiring M12. The first wiring M11 and the first wiring M12 are disposed inside the third interlayer insulating film 303. The first wiring M11 is disposed on the first contact via VA. The first wiring M11 is electrically connected to the first contact via VA. The first wiring M11 may be in contact with the first contact via VA. The first wiring M12 is disposed on the second contact via VB. The first wiring M12 is electrically connected to the second contact via VB. The first wiring M12 may be in contact with the second contact via VB.

In some embodiments, the first wiring M11 and the first wiring M12 may be formed using the subtractive process. Therefore, the width of the first wiring M11 and the width of the first wiring M12 may decrease as the distances between the respective components and the substrate 100 increase. The distance between the first wiring M11 and the first wiring M12 may increase as the distances between the respective components and the substrate 100 increase.

The first via layer V1 includes a fourth interlayer insulating film 304, a first via V11, and a first via V12. The first via V11 and the first via V12 are disposed inside the fourth interlayer insulating film 304. The first via V11 is disposed on the first wiring M11. The first via V11 is electrically connected to the first wiring M11. The first via V11 may be in contact with the first wiring M11. The first via V12 is disposed on the first wiring M12. The first via V12 is electrically connected to the first wiring M12. The first via V12 may be in contact with the first wiring M12.

The second metal layer M2 includes a fifth interlayer insulating film 305, a second wiring M21 and a second wiring M22. The second wiring M21 and the second wiring M22 are disposed inside the fifth interlayer insulating film 305. The second wiring M21 is disposed on the first via V11. The second wiring M21 is electrically connected to the first via V11. The second wiring M22 is disposed on the first via V12. The second wiring M22 is electrically connected to the first via V12.

In some embodiments, the first via V11, the second wiring M21, the first via V12 and the second wiring M22 may be formed using the semi-damascene process. For example, after filling a trench in the fourth interlayer insulating film 304 and forming a metal layer for covering or overlapping the upper side of the fourth interlayer insulating film 304, the metal layer may be etched using the subtractive process. Accordingly, the first via V11, the second wiring M21, the first via V12 and the second wiring M22 may be formed. The first via V11, the second wiring M21, the first via V12 and the second wiring M22 may each have an integral structure with no interface between them. The first via V11 and the second wiring M21 may be directly connected, and the first via V12 and the second wiring M22 may be directly connected. The first via V11, the second wiring M21, the first via V12 and the second wiring M22 may include the same material.

The width of the first via V11 and the width of the first via V12 may increase, as they go away from the substrate 100. The distance between the first via V11 and the first via V12 may decrease as the distance between the respective components and the substrate 100 increase. The width of the second wiring M21 and the width of the second wiring M22 may decrease as the distances between the respective components and the substrate 100 increase. The distance between the second wiring M21 and the second wiring M22 may increase as the distances between the respective components and the substrate 100 increase.

In some embodiments, the first wirings M11 and M21, the first via V11, the second wirings M12 and M22, and the second via V12 may each have a single conductive film structure.

The source/drain contact CA, the gate contact CB, the first contact via VA, the second contact via VB, the first wirings M11 and M21, the first via V11, the second wirings M12 and M22, and the second via V12 may each include, for example, at least one of a metal or a metal alloy. The source/drain contact CA, the gate contact CB, the first contact via VA, the second contact via VB, the first wirings M11 and M21, the first via V11, the second wirings M12 and M22, and the second via V12 may each include, for example, at least one of ruthenium (Ru), molybdenum (Mo), tungsten (W), and copper (Cu), but the technical idea of the present disclosure is not limited thereto.

The second via layer V2 includes a sixth interlayer insulating film 306, a first connecting via CV1, and a second connecting via CV2. The first connecting via CV1 and the second connecting via CV2 are disposed inside the sixth interlayer insulating film 306. The first connecting via CV1 is disposed on the second wiring M21. The first connecting via CV1 is electrically connected to the second wiring M21. The first connecting via CV1 may be in contact with the second wiring M21. The second connecting via CV2 is disposed on the second wiring M22. The second connecting via CV2 is electrically connected to the second wiring M22. The second connecting via CV2 may be in contact with the second wiring M22.

The third metal layer M3 includes a seventh interlayer insulating film 307 and a connecting wiring CM. The connecting wiring CM is disposed inside the seventh interlayer insulating film 307. The connecting wiring CM is disposed on the first connecting via CV1 and the second connecting via CV2. The connecting wiring CM is electrically connected to the first connecting via CV1 and the second connecting via CV2. The connecting wiring CM may be in contact with the first connecting via CV1 and the second connecting via CV2.

In some embodiments, the first connecting via CV1, the second connecting via CV2, and the connecting wiring CM may each be formed using a single damascene process. For example, the width of the first connecting via CV1, the width of the second connecting via CV2, and the width of the connecting wiring CM may each increase as the distances between the respective components and the substrate 100 increase. The distance between the first connecting via CV1 and the second connecting via CV2 may decrease as the distances between the respective components and the substrate 100 increase.

As another example, the first connecting via CV1, the second connecting via CV2, and the connecting wiring CM may be formed using a dual damascene process. Accordingly, it is possible to have an integral structure with no interface division between the connecting wiring CM and the first connecting via CV1, and between the connecting wiring CM and the second connecting via CV2.

In some embodiments, the first connecting via CV1, the second connecting via CV2, and the connecting wiring CM may each have a single conductive film structure.

The first connecting via CV1, the second connecting via CV2, and the connecting wiring CM may each include at least one of metal, conductive metal nitride, conductive metal carbide, conductive metal oxide, conductive metal carbonitride, and a two-dimensional material. The first connecting via CV1 and the second connecting via CV2 may include a material different from that of the second wiring M21 and the second wiring M22.

The first to seventh interlayer insulating films 301, 302, 303, 304, 305, 306, and 307 may be sequentially stacked. The first to seventh interlayer insulating films 301, 302, 303, 304, 305, 306, and 307 may each include, for example, at least one of silicon oxide, silicon nitride, silicon carbonitride, silicon oxynitride, and a low dielectric constant material. The dielectric constant of the low dielectric constant material may have a value smaller than 3.9, which is the dielectric constant of silicon oxide.

A sum of an area of the second wirings M21 and M22 forming the second connecting structure CS2 and an area of the second via V12 is smaller than an area of the first wirings M11 and M21 forming the first connecting structure CS1 and an area of the first via V11. Here, the areas may mean the areas of the upper sides of each of the wirings M11, M12, M21, and M22, or the areas of the upper sides of each of the vias V11 and V12.

A routing length of the second connecting structure CS2 is shorter than a routing length of the first connecting structure CS1.

Specifically, the first wiring M11, the first wiring M12, and the connecting wiring CM extend long in the first direction that is horizontal to the upper side 100A of the substrate 100. The second wiring M21 and the second wiring M22 extend long in the second direction that intersects the first direction.

In the second direction, the length of each of the second wirings M12 and M22 included in the second connecting structure CS2 is smaller than lengths of each of the first wirings M11 and M21. In the first direction, the length of the first wiring M12 is shorter than the length of the first wiring M11. The first wiring M12 may have a via shape. In the second direction, the length of the second wiring M22 is shorter than the length of the first wiring M12. The second wiring M22 may have a via shape. That is, the second connecting structure CS2 has a stacked via structure.

At least a part of the first connecting structure CS1 and the second connecting structure CS2 may be formed using the subtractive process or the semi-damascene process. For example, a metal layer including ruthenium (Ru) may be etched together with a hard mask disposed on the metal layer using reactive ion etching (RIE). Compared to the damascene process, such a process may use a higher energy, have a larger area of the metal layer to which plasma is applied, and have a longer etching time. Accordingly, more charge may be accumulated on the metal layer, and there may be a higher likelihood of occurrence of antenna effects. Therefore, the second gate insulating film 230 may be damaged.

An antenna ratio is expressed as a ratio of the area of the metal layer to which plasma is applied to the area of the gate insulating film, and the larger the antenna ratio is, the higher the likelihood of occurrence of the antenna effects may be.

The antenna effects may be improved by forming a diode connected to the metal in the substrate 100. However, the diode may reduce the usable area of the substrate 100. Additionally, if the thickness of the substrate 100 decreases, it may become difficult to form the diode.

In the semiconductor device according to some embodiments, the wirings M21 and M22 disposed at the uppermost parts of the first connecting structure CS1 and the second connecting structure CS2 are formed by the subtractive process, and the second connecting structure CS2 may have a sequentially stacked via shape. As a result, the area of the metal layer (i.e., the second connecting structure CS2) to which plasma is applied onto the second gate insulating film 230 may decrease, and the routing length of the second connecting structure CS2 may become shorter than the routing length of the first connecting structure CS1. Therefore, the antenna effects may be improved, and the performance and reliability of the semiconductor device may be improved.

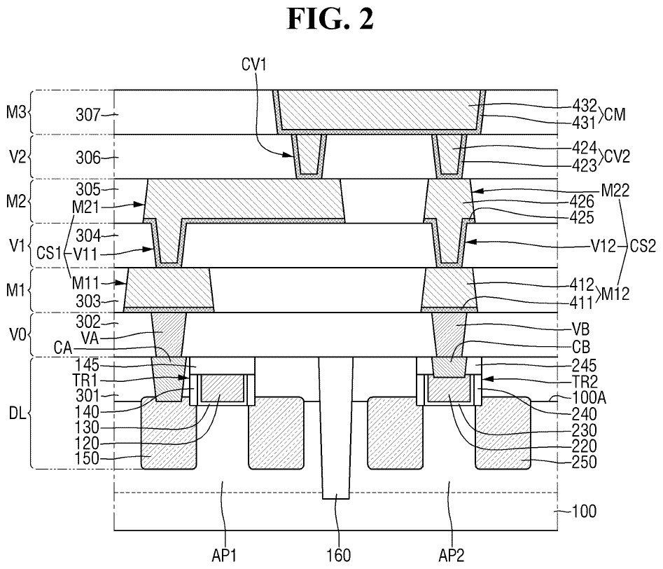

FIG. 2 is a diagram of a semiconductor device according to some embodiments. For convenience of explanation, points that are different from those explained using FIG. 1 will be mainly explained.

Referring to FIG. 2, in the semiconductor device according to some embodiments, the first wirings M11 and M21, the first via V11, the second wirings M12 and M22, the second via V12, the first connecting via CV1, the second connecting via CV2 and the connecting wiring CM may each have multiple conductive film structures.

The first wiring M11 and the first wiring M12 may each include a barrier film 411 and a filling film 412. The filling film 412 may be disposed on the barrier film 411. The barrier film 411 may extend along a bottom side of the filling film 412. The barrier film 411 may not extend along the side wall of the filling film 412. The barrier film 411 may expose the side wall of the filling film 412.

The first via V11 and the second wiring M21, and the first via V12 and the second wiring M22 may each have a barrier film 425 and a filling film 426. The filling film 426 may be disposed on the barrier film 425. The barrier film 425 may extend along the side walls and bottom side of the filling film 426 inside the fourth interlayer insulating film 304. The barrier film 425 may extend along the bottom side of the filling film 426 inside the fourth interlayer insulating film 304. The barrier film 425 may not extend along the side wall of the filling film 426 inside the fifth interlayer insulating film 305. The barrier film 425 may expose side walls of the filling film 426 inside the fifth interlayer insulating film 305.

The first connecting via CV1 and the second connecting via CV2 may each include a barrier film 423 and a filling film 424. The filling film 424 may be disposed on the barrier film 423. The barrier film 423 may extend along the side walls and bottom side of the filling film 424.

The connecting wiring CM may include a barrier film 431 and a filling film 432. The barrier film 431 may extend along the side walls and bottom side of the filling film 432.

Each of the barrier films 411, 425, 423, and 431 may function as an adhesion film.

The barrier films 411, 425, 423, and 431 may each include, for example, at least one of metal, conductive metal nitride, conductive metal carbide, conductive metal oxide, conductive metal carbonitride, and a two-dimensional material. The filling films 412, 426, 424, and 432 may include at least one of a metal and a metal alloy.

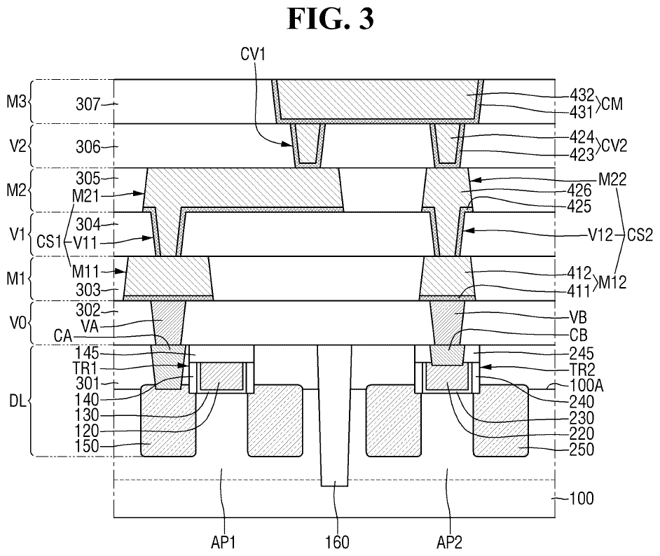

FIG. 3 is a diagram of a semiconductor device according to some embodiments. For convenience of explanation, points that are different from those explained using FIG. 2 will be mainly explained.

Referring to FIG. 3, in the semiconductor device according to some embodiments, the barrier film 425 is disposed on the side wall of the filling film 426 inside the fourth interlayer insulating film 304, but may not be placed on the bottom side of the filling film 426 inside the fourth interlayer insulating film 304. The barrier film 425 may expose the bottom side of the filling film 426 inside the fourth interlayer insulating film 304. Although the barrier film 425 extends along the side wall of the filling film 426 inside the fourth interlayer insulating film 304, it may not extend along the bottom side of the filling film 426 inside the fourth interlayer insulating film 304.

The barrier film 425 may be selectively deposited on the side walls of the trench inside the fourth interlayer insulating film 304, and the filling film 426 may fill or be in the trench in which the barrier film 425 is formed. The filling film 426 may be in contact with the wirings M11 and M12 inside the first metal layer M1.

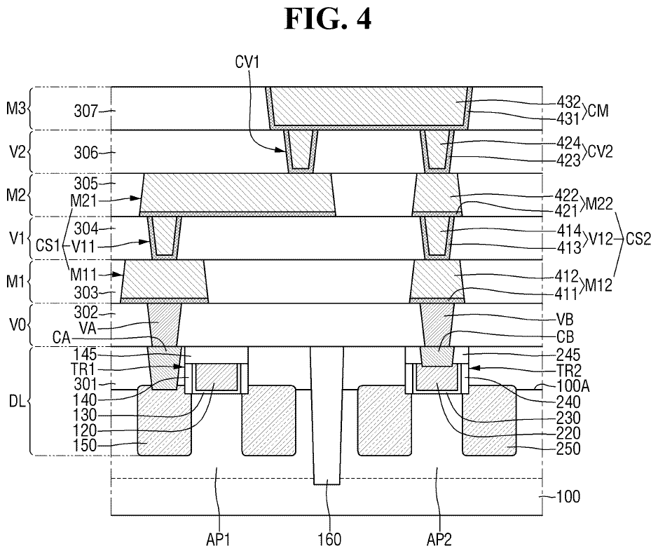

FIG. 4 is a diagram of a semiconductor device according to some embodiments. For convenience of explanation, points that are different from those explained using FIG. 2 will be mainly explained.

Referring to FIG. 4, in the semiconductor device according to some embodiments, the first via V11 and the first via V12 are formed using the single damascene process, and the second wiring M21 and the second wiring M22 may be formed using the subtractive process. Therefore, there may be an interface between the first via V11 and the second wiring M21, and between the first via V12 and the second wiring M22.

The first via V11 and the first via V12 may each include a barrier film 413 and a filling film 414. The barrier film 413 may extend along the side walls and bottom side of the filling film 414.

The second wiring M21 and the second wiring M22 may each include a barrier film 421 and a filling film 422. The barrier film 421 may extend along the bottom side of the filling film 422. The barrier film 421 may not extend along the side wall of the filling film 422. The barrier film 421 may expose the side wall of the filling film 422.

The barrier films 413 and 421 may each include, for example, at least one of metal, conductive metal nitride, conductive metal carbide, conductive metal oxide, a conductive metal carbonitride, and a two-dimensional material. The filling films 414 and 422 may include at least one of a metal and a metal alloy.

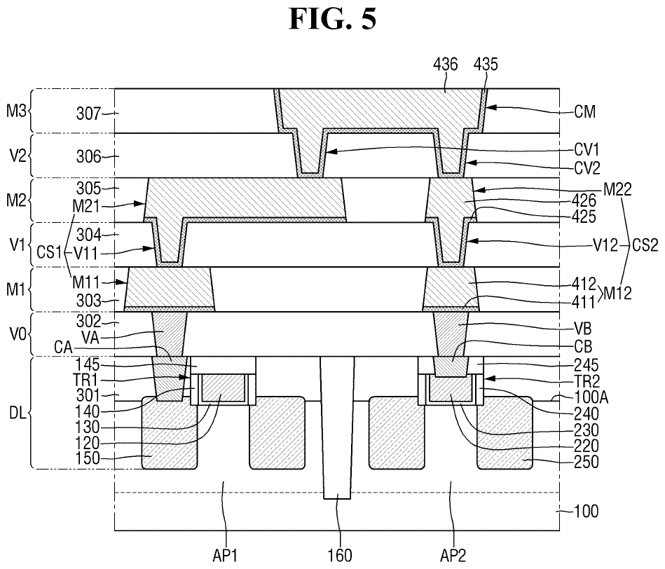

FIG. 5 is a diagram of a semiconductor device according to some embodiments. For convenience of explanation, points that are different from those explained using FIG. 2 will be mainly explained.

Referring to FIG. 5, in the semiconductor device according to some embodiments, the first connecting via CV1, the second connecting via CV2, and the connecting wiring CM may be formed using the dual damascene process. Accordingly, the first connecting via CV1, the second connecting via CV2, and the connecting wiring CM may have an integral structure without an interface division between them.

The first connecting via CV1, the second connecting via CV2, and the connecting wiring CM may each include a barrier film 435 and a filling film 436. The barrier film 435 may extend along the side walls and bottom side of the filling film 436.

Each barrier film 435 may include, for example, at least one of metal, conductive metal nitride, conductive metal carbide, conductive metal oxide, conductive metal carbonitride, and a two-dimensional material. The filling film 436 may include at least one of a metal and a metal alloy.

Like the barrier film 425 of FIG. 3, the barrier film 425 is disposed on the side wall of the filling film 426 inside the fourth interlayer insulating film 304, but may not be disposed on the bottom side of the filling film 426 inside the fourth interlayer insulating film 304.

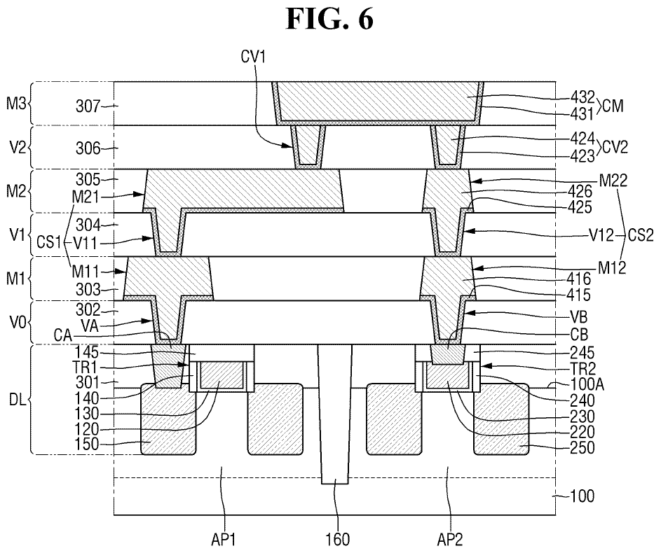

FIG. 6 is a diagram of a semiconductor device according to some embodiments. For convenience of explanation, points that are different from those explained using FIG. 2 will be mainly explained.

Referring to FIG. 6, in the semiconductor device according to some embodiments, the first contact via VA, the first wiring M11, the second contact via VB and the first wiring M12 may each be formed using a semi-damascene process. Therefore, the first contact via VA and the first wiring M11, and the second contact via VB and the first wiring M12 may each have an integral structure with no interface division between them.

The first contact via VA, the first wiring M11, the second contact via VB and the first wiring M12 may each include a barrier film 415 and a filling film 416. The barrier film 415 may extend along the side walls and bottom side of the filling film 416 inside the second interlayer insulating film 302. The barrier film 415 may extend along the bottom side of the filling film 416 inside the third interlayer insulating film 303. The barrier film 415 may not extend along the side wall of the filling film 416 inside the third interlayer insulating film 303. The barrier film 415 may expose the side wall of the filling film 416 inside the third interlayer insulating film 303.

Like the barrier film 425 of FIG. 3, the barrier film 425 is disposed on the side wall of the filling film 426 inside the fourth interlayer insulating film 304, but may not be disposed on the bottom side of the filling film 426 inside the fourth interlayer insulating film 304.

The first connecting via CV1, the second connecting via CV2, and the connecting wiring CM may be formed using the dual damascene process, as in FIG. 5.

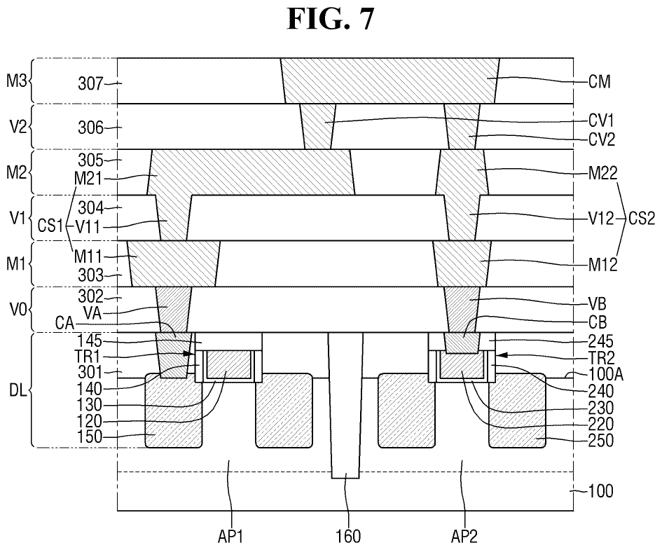

FIG. 7 is a diagram of a semiconductor device according to some embodiments. For convenience of explanation, points that are different from those explained using FIG. 1 will be mainly explained.

Referring to FIG. 7, in the semiconductor device according to some embodiments, the first wiring M11 and the first wiring M12 may be formed using the single damascene process. Therefore, the width of the first wiring M11 and the width of the first wiring M12 may increase as the distances between the respective components and the substrate 100 increase. The distance between the first wiring M11 and the first wiring M12 may decrease as the distances between the respective components and the substrate 100 increase.

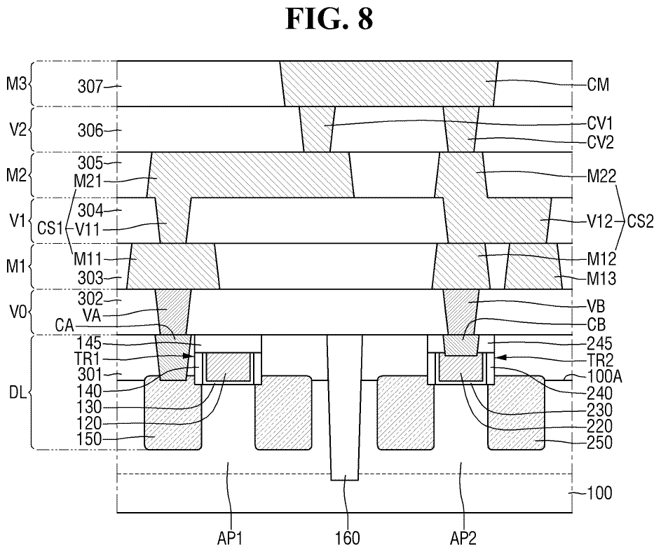

FIG. 8 is a diagram of a semiconductor device according to some embodiments. For convenience of explanation, points that are different from those explained using FIG. 1 will be mainly explained.

Referring to FIG. 8, in the semiconductor device according to some embodiments, at least one of the second vias V12 of the second connecting structure CS2 may have a via jumper structure. The via jumper is a via for electrically connecting any two points, and may refer to a via that is relatively longer than the via.

For example, a first wiring M12 and a first wiring M13 may be disposed inside the first metal layer M1. The first wiring M12 and the first wiring M13 may be spaced apart from each other. The first wiring M12 and the first wiring M13 may be adjacent to each other. The first via V12 may be disposed on the first wiring M12 and the first wiring M13. The second via V12 may electrically connect the first wiring M12 and the first wiring M13. The first via V12 may be in contact with the first wiring M12 and the first wiring M13.

In an arbitrary direction, the length of the first via V12 may be longer than the length of the first via V11.

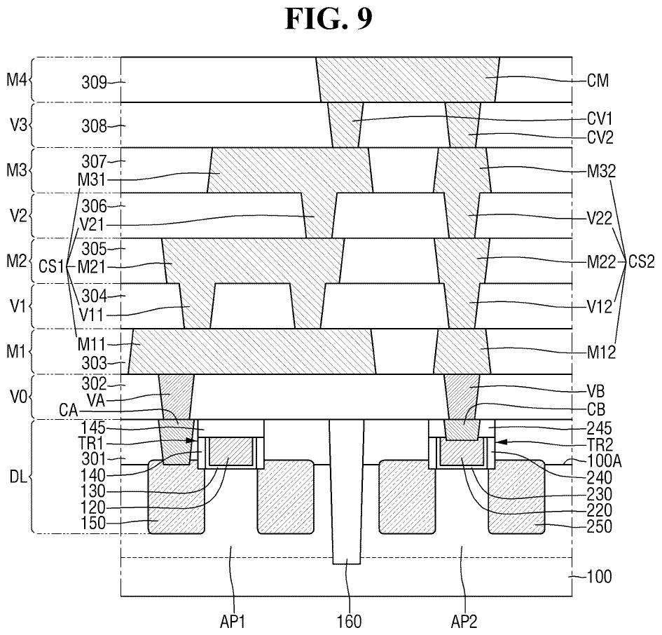

FIG. 9 is a diagram of a semiconductor device according to some embodiments. For convenience of explanation, points that are different from those explained using FIG. 1 will be mainly explained.

Referring to FIG. 9, the semiconductor device according to some embodiments may further include a third via layer V3 and a fourth metal layer M4 that are sequentially stacked on the third metal layer M3. Eighth and ninth interlayer insulating films 308 and 309 may be sequentially stacked on the seventh interlayer insulating film 307. The third metal layer M3 may include a third wiring M31 and a third wiring M32 inside the seventh interlayer insulating film 307. The third via layer V3 may include a first connecting via CV1 and a second connecting via CV2 inside the eighth interlayer insulating film 308. The fourth metal layer M4 may include a connecting wiring CM inside the ninth interlayer insulating film 309.

The first connecting structure CS1 may further include a second via V21 and a third wiring M31. The second connecting structure CS2 may further include a second via V22 and a third wiring M32.

In the first direction, the lengths of each of the second wirings M12, M22, and M32 included in the second connecting structure CS2 are shorter than the lengths of the lengths of each of the first wirings M11, M21, and M31. The third wiring M32 may have a via shape. That is, the second connecting structure CS2 has a stacked via structure.

In some embodiments, the first via V11, the second wiring M21, the first via V12 and the second wiring M22 may be formed using the dual damascene process. Accordingly, it is possible to have an integral structure without an interface division between the first via V11 and the second wiring M21, and between the first via V12 and the second wiring M22.

The width of the first via V11, the width of the second wiring M21, the width of the first via V12, and the width of the second wiring M22 may increase as the distances between the respective components and the substrate 100 increase. The distance between the first via V11 and the first via V12, and the distance between the second wiring M21 and the second wiring M22 may decrease as the distances between the respective components and the substrate 100 increase.

The third wiring M31, the second via V21, the third wiring M32 and the second via V22 may each be formed using the semi-damascene process. Accordingly, the third wiring M31, the second via V21, the third wiring M32 and the second via V22 may each have an integral structure without an interface division between them.

The width of the second via V21 and the width of the second via V22 may each increase as the distances between the respective components and the substrate 100 increase. The distance between the second via V21 and the second via V22 may decrease as the distances between the respective components and the substrate 100 increase. The width of the third wiring M31 and the width of the third wiring M32 may decrease as the distances between the respective components and the substrate 100 increase. The distance between the third wiring M31 and the third wiring M32 may increase as the distances between the respective components and the substrate 100 increase.

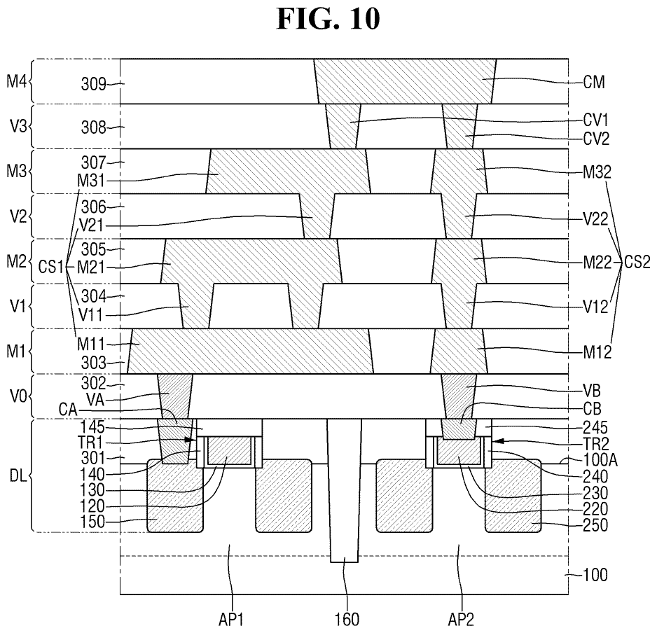

FIG. 10 is a diagram of a semiconductor device according to some embodiments. For convenience of explanation, points that are different from those explained using FIG. 9 will be mainly explained.

Referring to FIG. 10, in the semiconductor device according to some embodiments, the first via V11, the second wiring M21, the first via V12 and the second wiring M22 may be formed using a semi-damascene process. The width of the first via V11 and the width of the first via V12 may increase as the distances between the respective components and the substrate 100 increase. The distance between the first via V11 and the first via V12 may decrease as the distances between the respective components and the substrate 100 increase. The width of the second wiring M21 and the width of the second wiring M22 may decrease as the distances between the respective components and the substrate 100 increase. The distance between the second wiring M21 and the second wiring M22 may increase as the distances between the respective components and the substrate 100 increase.

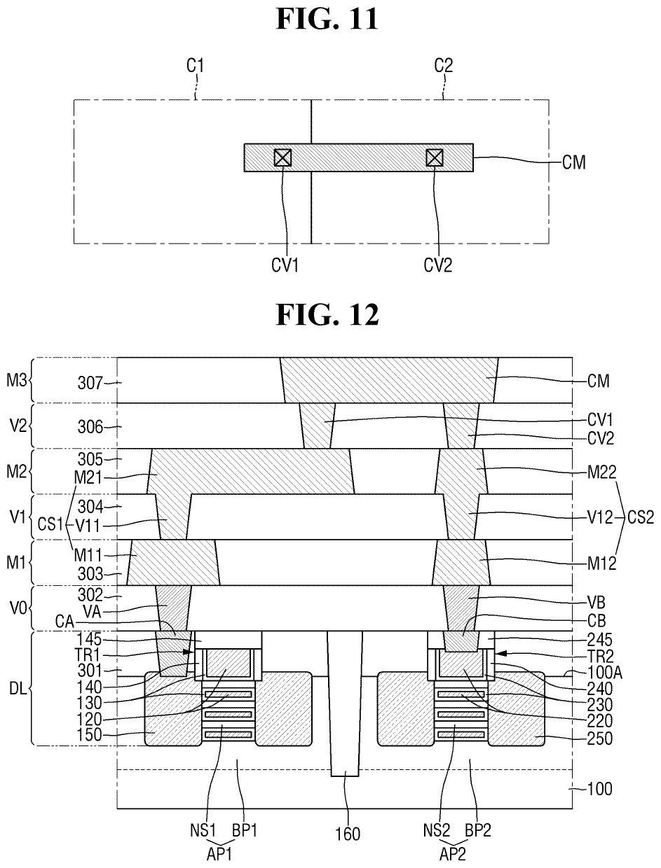

FIG. 11 is a diagram of a semiconductor device according to some embodiments.

Referring to FIG. 11, the semiconductor device according to some embodiments may include cells C1 and C2.

The number of cells C1 and C2 included in the semiconductor device and the arrangement of the cells C1 and C2 are not limited thereto. The cells C1 and C2 are units of layout included in an integrated circuit, may be designed to perform a predetermined function, and may be referred to as standard cells. The cells C1 and C2 may be any functional or logic cell that provides a logic or storage function, respectively. For example, the cells C1 and C2 may each be a NAND, an AND, a NOR, an OR, a XOR, an inverter, an adder, a flip-flop or a latch.

The first cell C1 may be electrically connected to the second cell C2 through the first connecting via CV1, the connecting wiring CM, and the second connecting via CV2. The connecting vias CV1 and CV2 and the connecting wiring CM may be wirings and vias that connect the cells C1 and C2. For example, the source/drain of the transistor of the first cell C1 may be electrically connected to the gate of the second cell C2.

The first cell C1 may include the first transistor TR1, the source/drain contact CA, the first contact via VA, the first connecting structure CS1 and the first connecting via CV1 of FIGS. 1 to 10, and the second cell C2 may include the second transistor TR2, the gate contact CB, the second contact via VB, the second connecting structure CS2 and the second connecting via CV2 of FIGS. 1 to 10. The first connecting via CV1, the second connecting via CV2 and the connecting wiring CM may be the first connecting via CV1, the second connecting via CV2 and the connecting wiring CM of FIGS. 1 to 10.

FIG. 12 is a diagram of a semiconductor device according to some embodiments. For convenience of explanation, points that are different from those explained using FIG. 1 will be mainly explained.

Referring to FIG. 12, in the semiconductor device according to some embodiments, each of the active patterns AP1 and AP2 may be a multi-channel active pattern. For example, the first active pattern AP1 may include a first lower pattern BP1 and a plurality of first sheet patterns NS1. The second active pattern AP2 may include a second lower pattern BP2 and a plurality of second sheet patterns NS2. In the semiconductor device according to some embodiments, each of the active patterns AP1 and AP2 may be an active pattern that includes nanosheets or nanowires.

Each of the lower patterns BP1 and BP2 may protrude or extend from the substrate 100. For example, each of the lower patterns BP1 and BP2 may protrude or extend from the upper side 100A of the substrate 100. Each of the lower patterns BP1 and BP2 may be a fin type pattern.

The plurality of first sheet patterns NS1 may be disposed on the first lower pattern BP1. The plurality of first sheet patterns NS1 may be spaced apart from the upper side of the first lower pattern BP1 in a vertical direction that is perpendicular to the first and second directions. The plurality of second sheet patterns NS2 may be disposed on the second lower pattern BP2. The plurality of second sheet patterns NS2 may be spaced apart from the upper side of the second lower pattern BP2 in the vertical direction. Although three sheet patterns NS1 and NS2 are each shown as being disposed in the vertical direction, this example is only for convenience of explanation, and is not limited thereto.

Each of the lower patterns BP1 and BP2 may be formed by etching a part of the substrate 100, or may include an epitaxial layer grown from the substrate 100. Each of the lower patterns BP1 and BP2 may include silicon or germanium, which is an elemental semiconductor material. Further, each of the lower patterns BP1 and BP2 may include a compound semiconductor, and may include, for example, a group IV-IV compound semiconductor or a group III-V compound semiconductor.

Each of the sheet patterns NS1 and NS2 may include silicon or germanium which is an elemental semiconductor material, a group IV-IV compound semiconductor, or a group III-V compound semiconductor.

The first gate electrode 120 may wrap or at least partially surround each first sheet pattern NS1. The first gate electrode 120 may be further disposed between first sheet patterns NS1 adjacent to each other in the vertical direction, and between the first lower pattern BP1 and the first sheet pattern NS1. The second gate electrode 220 may wrap or at least partially surround each second sheet pattern NS2. The second gate electrode 220 may be further disposed between the second sheet patterns NS2 adjacent to each other in the vertical direction, and between the second lower pattern BP2 and the second sheet pattern NS2.

The first gate insulating film 130 may extend along the upper side of the first lower pattern BP1. The first gate insulating film 130 may wrap or at least partially surround the plurality of first sheet patterns NS1. The first gate insulating film 130 may be disposed along the periphery of the first sheet pattern NS1. The first gate electrode 120 is disposed on the first gate insulating film 130. The first gate insulating film 130 may be in contact with the first source/drain pattern 150.

The second gate insulating film 230 may extend along the upper side of the second lower pattern BP2. The second gate insulating film 230 may wrap or at least partially surround the plurality of second sheet patterns NS2. The second gate insulating film 230 may be disposed around the periphery of the second sheet pattern NS2. The second gate electrode 220 is disposed on the second gate insulating film 230. The second gate insulating film 230 may be in contact with the second source/drain pattern 250.

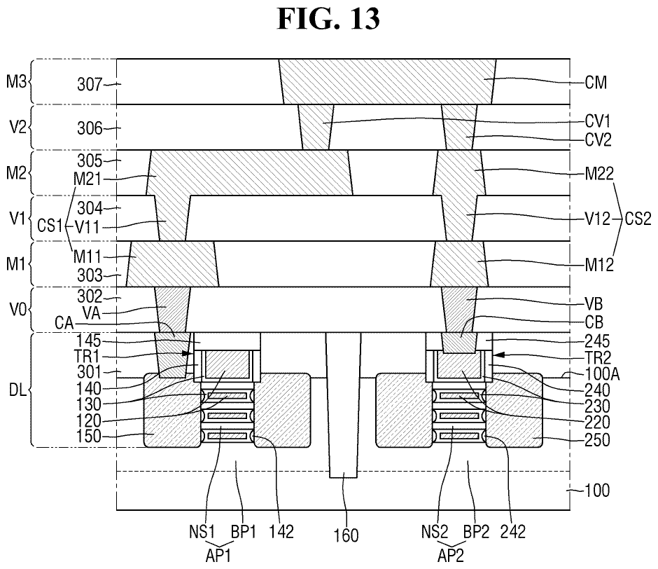

FIG. 13 is a diagram of a semiconductor device according to some embodiments. For convenience of explanation, points different from those explained using FIG. 12 will be mainly explained.

Referring to FIG. 13, the semiconductor device according to some embodiments may further include a first inner spacer 142 and a second inner spacer 242.

The first inner spacers 142 may be disposed between the first sheet patterns NS1 adjacent to each other in the vertical direction, and between the first lower pattern BP1 and the first sheet pattern NS1. The first inner spacer 142 may be disposed between the first gate insulating film 130 and the first source/drain pattern 150. The second inner spacer 242 may be disposed between second sheet patterns NS2 adjacent to each other in the vertical direction, and between the second lower pattern BP2 and the second sheet pattern NS2. The second inner spacer 242 may be disposed between the second gate insulating film 230 and the second source/drain pattern 250.

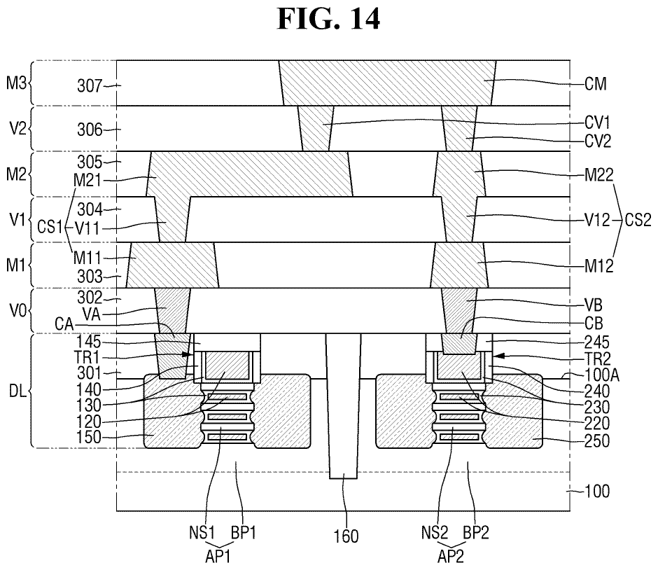

FIG. 14 is a diagram of a semiconductor device according to some embodiments. For convenience of explanation, points different from those explained using FIG. 12 will be mainly explained.

Referring to FIG. 14, in the semiconductor device according to some embodiments, the first source/drain pattern 150 may include an outer wall that is on the first sheet pattern NS1 and the first gate insulating film 130. The outer wall of the first source/drain pattern 150 may have a nonlinear shape (e.g., a wavy shape).

The second source/drain pattern 250 may include an outer wall that is on the second sheet pattern NS2 and the second gate insulating film 230. The outer wall of the second source/drain pattern 250 may have a nonlinear shape (e.g., a wavy shape).

Although the embodiments of the present disclosure have been described above with reference to the accompanying drawings, the present disclosure is not limited to the above embodiments, and may be fabricated in various forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A semiconductor device comprising:
a substrate;
a first transistor on the substrate;
a first contact on a source/drain pattern of the first transistor;
a second transistor on the substrate;
a second contact on a gate electrode of the second transistor;
a first connecting structure that comprises at least one first wiring and at least one first via that are alternately stacked on the first contact;
a second connecting structure that comprises at least one second wiring and at least one second via that are alternately stacked on the second contact;
a first connecting via on the first connecting structure;
a second connecting via on the second connecting structure; and
a connecting wiring on the first connecting via and the second connecting via.

2. The semiconductor device of claim 1, wherein the first connecting structure and the second connecting structure are electrically connected by the connecting wiring, the first connecting via, and the second connecting via.

3. The semiconductor device of claim 1, wherein each of the at least one second via is respectively on each of the at least one second via.

4. The semiconductor device of claim 1, wherein:
each of the at least one first wiring comprises a first width and is separated from the substrate by a first distance,
each of the at least one first via comprises a second width and is separated from the substrate by a second distance,
each of the at least one second wiring comprises a third width and is separated from the substrate by a third distance,
a first set of widths from among the first width, the second width, and third width decreases as a respective first set of distances from among the first distance, the second distance, and the third distance increases, and
a second set of widths from among the first width, the second width, and the third width increases as a respective second set of distances from among the first distance, the second distance, and the third distance increases.

5. The semiconductor device of claim 1, wherein:
the at least one first via comprises a third via,
the at least one first wiring comprises a third wiring that is electrically connected to the third via,
the at least one second via comprises a fourth via,
the at least one second wiring comprises a fourth wiring that is electrically connected to the fourth via,
the third via and the fourth via are on a same via layer,
the third wiring and the fourth wiring are on a same metal layer,
a width of the third via increases as a distance between the third via and the substrate increases,
a width of the fourth via increases as a distance between the fourth via and the substrate increases,
a width of the third wiring decreases as a distance between the third wiring and the substrate increases, and
a width of the fourth wiring decreases as a distance between the fourth wiring and the substrate increases.

6. The semiconductor device of claim 5, wherein:
the third via and the third wiring are directly connected, and
the fourth via and the fourth wiring are directly connected.

7. The semiconductor device of claim 1, wherein:
the at least one first wiring comprises a third wiring,
the at least one second wiring comprises a fourth wiring,
the third wiring and the fourth wiring are on a same metal layer,
a width of the third wiring decreases as a distance between the third wiring and the substrate increases, and
and a width of the fourth wiring decreases as a distance between the fourth wiring and the substrate increases.

8. The semiconductor device of claim 7, wherein:
the third wiring is electrically connected to the first connecting via, and
the at least one second wiring is electrically connected to the second connecting via.

9. The semiconductor device of claim 1, wherein:
the at least one first via comprises a third via,
the at least one first wiring comprises a third wiring that is electrically connected to the third via,
the at least one second via comprises a fourth via,
the at least one second wiring comprises a fourth wiring that is electrically connected to the fourth via,
the third via and the fourth via are on a same via layer,
the third wiring and the fourth wiring are on a same metal layer,
a width of the third via increases as a distance between the third via and the substrate increases,
a width of the fourth via increases as a distance between the fourth via and the substrate increases,
a width of the third wiring increases as a distance between the third wiring and the substrate increases, and
a width of the fourth wiring increases as a distance between the fourth wiring and the substrate increases.

10. The semiconductor device of claim 1, wherein:
the at least one first via comprises a third via,
the at least one second via comprises a fourth via,
the third via and the fourth via are on a same via layer, and
a length of the fourth via is greater than a length of the third via.

11. The semiconductor device of claim 1, wherein:
a width of the first connecting via increases as a distance between the first connecting via and the substrate increases,
a width of the second connecting via increases as a distance between the second connecting via and the substrate increases, and
a width of the connecting wiring increases as a distance between the connecting wiring and the substrate increases.

12. A semiconductor device comprising:
a substrate;
a first transistor on the substrate;
a first contact on a source/drain pattern of the first transistor;
a second transistor on the substrate;
a second contact on a gate electrode of the second transistor;
a first connecting structure on the first contact, wherein the first connecting structure comprises at least one first wiring and at least one first via;
a second connecting structure on the second contact, wherein the second connecting structure comprises at least one second wiring and at least one second via;
a first connecting via on the first connecting structure;
a second connecting via on the second connecting structure; and
a connecting wiring on the first connecting via and the second connecting via,
wherein in a first direction in which each of the at least one first wiring extends, a length of each of the at least one second wiring is less than a length of each of the at least one first wiring, and
a distance between a third wiring at an uppermost part of the at least one first wiring and a fourth wiring at an uppermost part of the at least one second wiring increases as a distance between the third wiring and the substrate increases or as a distance between the fourth wiring and the substrate increases.

13. The semiconductor device of claim 12,
wherein the at least one first via includes a third via that is electrically connected to the third wiring,
the third wiring comprises a first barrier layer and a first filling layer on the first barrier layer,
the third via comprises a second barrier layer and a second filling layer on the second barrier layer,
the fourth wiring comprises a third barrier layer and a third filling layer on the third barrier layer,
the fourth via comprises a fourth barrier layer and a fourth filling layer on the fourth barrier layer,
the second barrier layer of the third via extends along a side wall and a bottom side of the second filling layer of the third via, and
the first barrier layer of the third wiring extends along a bottom side of the first filling layer of the third wiring and does not extend along a side wall of the first filling layer of the third wiring.

14. The semiconductor device of claim 13,
wherein the second barrier layer of the third via is directly connected to the third barrier layer of the fourth wiring, and
the first filling layer of the third wiring is directly connected to the third filling layer of the fourth wiring.

15. The semiconductor device of claim 12,
wherein the first contact comprises a source/drain contact and a first contact via,
the second contact comprises a gate contact and a second contact via,
the at least one first wiring comprises a fifth wiring that is electrically connected to the first contact via,
the at least one second wiring comprises a sixth wiring that is electrically connected to the second contact via,
a width of the first contact via increases as a distance between the first contact via and the substrate increases,
and a width of the second contact via increase increases as a distance between the second contact via and the substrate increases,
a width of the fifth wiring decreases as a distance between the fifth wiring and the substrate increases, and
a width of the sixth wiring decreases as a distance between the sixth wiring and the substrate increases.

16. The semiconductor device of claim 15, wherein:
the first contact via and the fifth wiring are directly connected, and
the second contact via and the sixth wiring are directly connected.

17. The semiconductor device of claim 12, wherein:
each of the at least one first wiring comprises a first width and is separated from the substrate by a first distance,
each of the at least one first via comprises a second width and is separated from the substrate by a second distance,
each of the at least one second wiring comprises a third width and is separated from the substrate by a third distance,
a first set of widths from among the first width, the second width, and third width decreases as a respective first set of distances from among the first distance, the second distance, and the third distance increases, and
a second set of widths from among the first width, the second width, and the third width increases as a respective second set of distances from among the first distance, the second distance, and the third distance increases.

18. A semiconductor device comprising:
a first cell;
a first connecting via on the first cell;
a second cell;
a second connecting via on the second cell; and
a connecting wiring that is on and electrically connects the first connecting via and the second connecting via,
wherein the first cell comprises:
a first transistor,
a first contact on a source/drain pattern of the first transistor, and
a first connecting structure that comprises at least one first wiring and at least one first via, wherein the first connecting structure electrically connects the first contact and the first connecting via,
wherein the second cell comprises:
a second transistor,
a second contact on a gate electrode of the second transistor, and
a second connecting structure that comprises at least one second wiring and at least one second via, wherein the second connecting structure electrically connects the second contact and the second connecting via.

19. The semiconductor device of claim 18, wherein a sum of an area of an upper side of the at least one second wiring and an area of the at least one second via is less than a sum of an area of an upper side of the at least one first wiring and an area of the at least one first via.

20. The semiconductor device of claim 18, wherein:
the at least one first wiring comprises a third wiring that is electrically connected to the first connecting via,
the at least one second wiring comprises a fourth wiring that is electrically connected to the second connecting via, and
the third wiring and the fourth wiring comprise a first material, and
the first connecting via and the second connecting via comprise a second material.
